(19) United States
(12) Patent Application Publication
(10) Pub. No.: US 2008/0226842 A1
(43) Pub. Date: Sep. 18, 2008

(54) Lazy Susan Tool Layout for Light-Activated ALD

(75) Inventor: Mirko Vukovic, Slingerlands, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: Tokyo Electron Limited, Tokyo (JP)

(21) Appl. No.: 11/537,286

(22) Filed: Sep. 29, 2006

(51) Int. Cl. C23C 16/48; C23C 16/44

(52) U.S. Cl. 427/595; 118/730

(57) ABSTRACT

An atomic layer deposition (ALD) module is provided with a rotatable carrier plate that holds a plurality of wafer holders at equally spaced angular positions. The plate is rotated to carry the wafers through a plurality of processing stations arranged at similarly equally spaced angular intervals around the axis of rotation of the rotatable plate. Rotation of the carrier plate carries a plurality of substrates successively through a plurality of pairs of stations, each pair including a precursor deposition station and a light activation station. A plurality of rotations may be used to apply a complete ALD film on the substrates. Wafers in different holders on the carrier are simultaneously processed in different stations, with some having precursor deposited thereon and others having the precursor thereon activated by light. One or more transfer stations can be included for loading or unloading wafers to and from the carrier. The number of holders on the carrier equals the number of stations in the module. Curtains and purge gas flow direction features keep precursor gas from the deposition stations from entering the activation or transfer stations.

This invention relates to processing tool configurations and cycling for Atomic Layer Deposition (ALD).

### BACKGROUND OF THE INVENTION

In atomic layer deposition (ALD), very thin films, for example of metal, are deposited on a substrate by rapid cycling of repeated depositions of a precursor with each deposition followed by an activation step. Often twenty or more cycles are required to successfully deposit a film. The technology is relatively new, and few known processes provide the efficiency desirable for commercial ALD. All such known processes have unsolved problems that interfere with process efficiency.

Accordingly, efficient ALD processes arc needed.

### SUMMARY OF THE INVENTION

An objective of the present invention is to provide an efficient ALD process.

A further objective of the present invention is to provide an ALD process in which process parameters can be changed quickly going from deposition to activation to deposition, etc. on a given wafer.

A more particular objective of the invention is to rapidly change the atmosphere in which the wafer is situated from one containing precursor to a clean atmosphere for activation of the deposited precursor on the wafer.

According to principles of the present invention, a moveable wafer holder carrier is provided on which a wafer can be moved through a series of process stations, including at least one station on which precursor is deposited on the wafer and one in which deposited precursor on the wafer is activated.

According to other principles of the invention, a multiple wafer holder carrier is provided on which a plurality of wafers are held so that at least one wafer can be coated with precursor while the precursor on at least one other wafer is being activated.

In certain embodiments of the invention, a rotating index plate is provided in an ALD processing module on which is a plurality of wafer holders. The module contains a plurality of processing stations including at least one precursor deposition station and at least one activation station. Wafers are moved on a holder in a plurality of cycles that each includes successively moving the wafer to the deposition station and then to the activation station. One wafer can be deposited with precursor at a deposition station while the coating on another wafer is being activated at an activation station. Preferably, the number of wafer holders on the index plate equals the number of stations for maximum efficiency.

In accordance with the illustrated embodiments of the invention, structure is provided to isolate the wafers in the precursor deposition stations from wafers in the activation or transfer stations. For example, curtain structure coupled with purge gas flow and exhaust paths surround some of the stations to isolate them from others. In the illustrated embodiment, curtains and exhaust ports surround the activation and transfer stations with the precursor deposition stations depositing precursor while in communication with an overall plenum chamber that includes all of the stations.

A plurality of pairs of processing stations can be provided in the ALD module and a corresponding plurality of pairs of wafer holders can be provided on the index plate. For example, two, four or six holders can be provided to carry wafers through one, two or three pairs of deposition and activation stations. Thus, two, four or six wafers can be moved successively through the two, four or six stations that alternatively deposit precursor coatings and activate the deposited coatings until enough cycles arc performed to complete a film on each wafer. Two, four or six wafers can be processed simultaneously. An additional transfer station can be provided along with an additional holder on the carrier so that wafers can be loaded onto and unloaded from the carrier while others are being processed.

The preferred embodiments of the invention employ light activated precursors, and the activation stations arc light activation stations. Wafers are indexed to precursor stations at which precursor, for example an organic metal-containing precursor gas, is directed onto the wafer surface where some of it is adsorbed. Then the carrier is indexed to move the coated wafer to a light activation where light is directed onto the surface of the wafer to disassociate the adsorbed precursor and leave a portion of a metal film on the wafer. The indexing of the earner can also move other wafers from activation stations to deposition stations, from an activation station to a transfer station or from a transfer station to a deposition station.

These and other objects and advantages of the present invention will be more readily apparent from the following detailed description of illustrated embodiments of the invention.

### BRIEF DESCRIPTION OF THE DRAWINGS

FIG. 1 is a diagrammatic top view of a portion of a semiconductor wafer processing tool having an ALD module embodying principles of the present invention.

FIG. 1A is cross-sectional view of the processing tool of FIG. 1.

FIG. 2 is a perspective diagram showing an index plate of the module of FIGS. 1 and 1A.

FIG. 3 is a perspective diagram showing a curtain arrangement of the module of FIGS. 1 and 1A.

FIG. 4 is a cross-sectional view of a precursor shower head of the module of FIGS. 1 and 1A.

FIGS. 4A and 4B are diagrams of alternative MEMS elements for the showerhead of FIG. 4.

### DETAILED DESCRIPTION

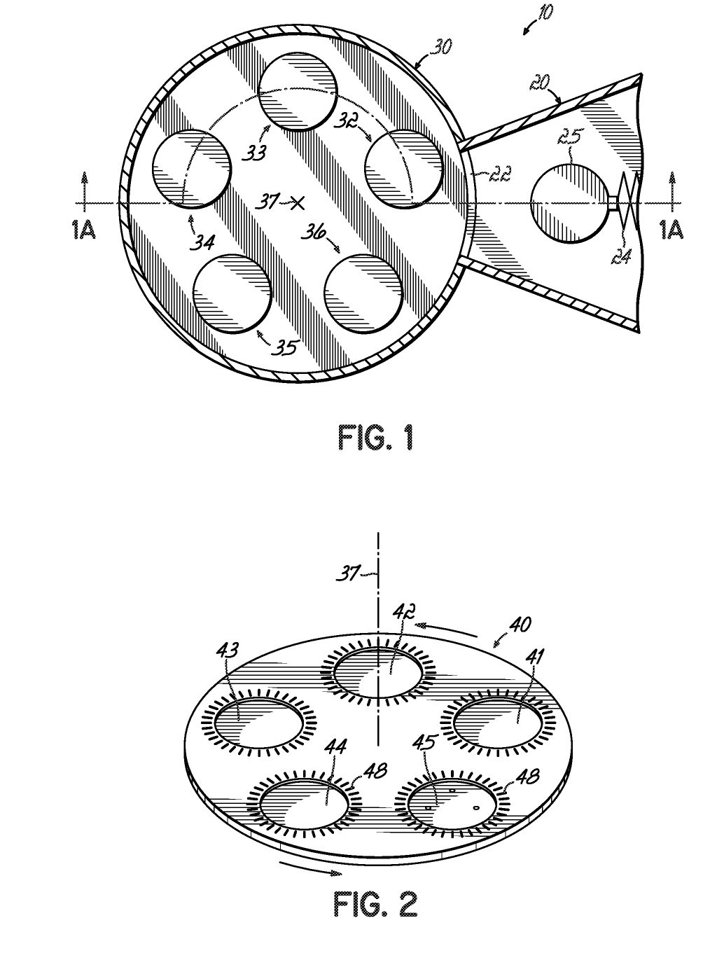

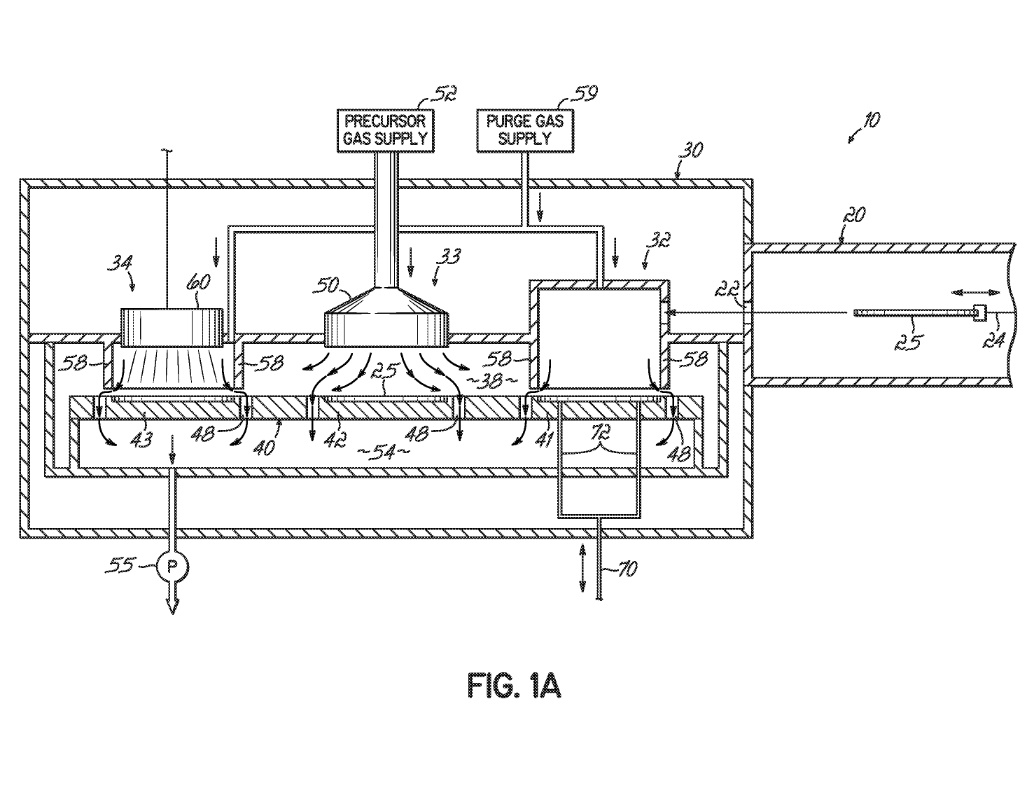

FIG. 1 is a diagrammatic top view of a portion of a semiconductor wafer processing tool 10 that includes a transfer module 20 and an atomic layer deposition (ALD) module 30. The ALD module 30 is coupled to the transfer module 20 through a gate valve 22. The transfer module 20 has a transfer arm 24 that loads wafers 25 into, and removes wafers 25 from, a wafer transfer station 32 of the ALD module 30, as well as to and from other modules (not shown) of the processing tool 10.

The ALD module 30 includes, in addition to the wafer transfer station 32, two precursor deposition stations 33 and 35, and two light activation stations 34 and 36. The stations 32-36 are located at equally angularly-spaced positions, at equal radii from a vertical centerline 37, in an ALD processing chamber 38 of the ALD module 30. The stations are arranged around the centerline 37 in the chamber 38 in the order of: transfer station 32, deposition station 33, activation station 34, deposition station 35 and activation station 36, as illustrated in FIG. 1.

The provision for a separate transfer station 32 is optional, with direct loading to and from one of the other stations can be employed.

In the chamber 38 is situated a rotatable index plate 40 having five generally identical wafer supports 41-45 located thereon, as illustrated in FIG. 2. The wafer supports 41-45 arc equally spaced at 72 degree angular positions on the plate 40 such that the index plate 40 when rotated about axis 37, can align the supports 41-45 simultaneously with the stations 32-36, and can index each of the supports from the transfer station 32, successively through the stations 33-36, and then again to the station 32.

FIG. 1A is a cross-sectional view through the module 30 of FIG. 1 showing the index plate 40 in the chamber 38. As illustrated, the wafer holder 41 is shown at transfer station 32, wafer holder 42 is shown at deposition station 33 and wafer holder 43 is shown at activation station 34. The two precursor deposition stations 33 and 35 are provided with a downwardly facing shower head 50 centered over the station to direct precursor gas from a gas supply 52 onto the upwardly facing surface of a wafer 25 when positioned at the precursor station 33 or 35.

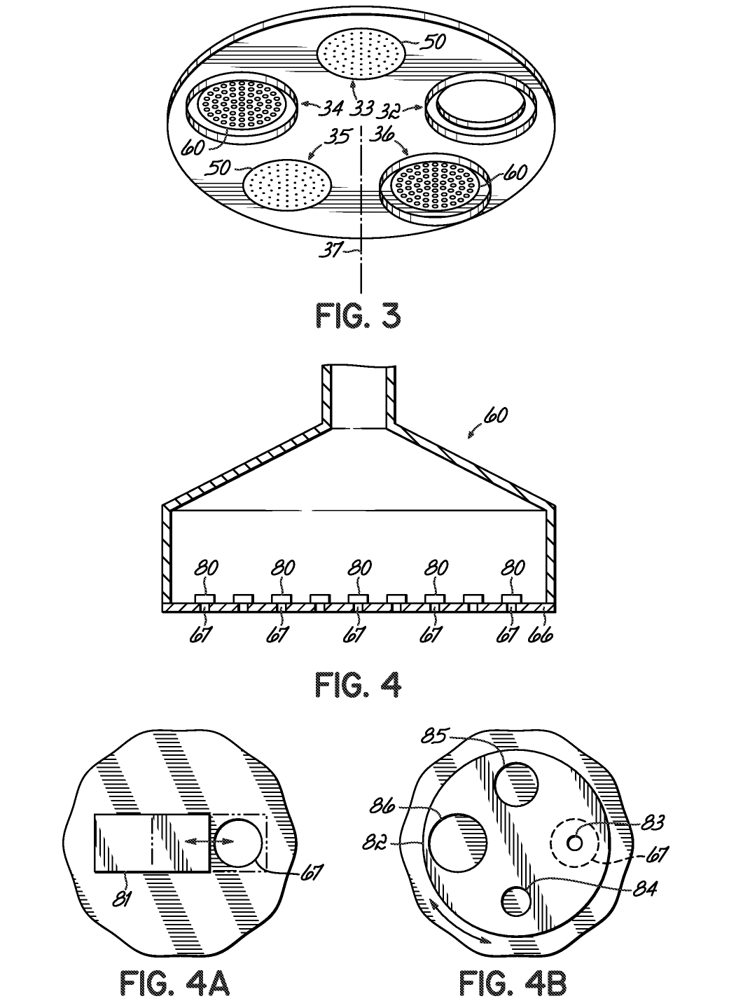

Around each wafer holder 41 -45 in the index plate 40 is a ring of exhaust openings 48 (FIGS. 1A and 2) that communicate with an exhaust chamber 54 below the index plate 40. A vacuum pump 55 is connected to the exhaust chamber 54 to draw gas from the chamber 38 above the plate 40 through the holes 48. Because the precursor chambers 33 and 35 are open to the chamber 38, precursor gas will flow beyond the rings or holes 48 surrounding the stations 33 and 35 and throughout the chamber 38. A set of curtains or walls 58 (FIGS. 1A and 3) project downwardly from the upper wall of the chamber 38 to surround the activation stations 34 and 36 and the transfer station 32 to keep the precursor gas flow from chamber 38 into the space over the wafers 25 at these stations to a minimum.

A neutral or purge gas is fed from a source 59 into the activation chambers 34 and 36 and the transfer chamber 32. The bottom ends of the curtains 58 are closely spaced to the index plate 40 above the openings 48. Purge gases from the stations 32, 34 and 36 and the precursor gas from the surrounding chamber 38 are exhausted via the annular area around these stations that lies beneath the curtains through the openings 48 and into the exhaust chamber 54, thereby effectively isolating the chambers 32, 34 and 36 from the chamber 38.

An activating light source 60 is provided at each of the light activation stations 34 and 36, above the wafers 25, to direct light of a character that is effective to activate the precursor that was deposited on die wafers 25 when they were at the precursor deposition stations 33 and 35, respectively. The activating light source 60 may provide light with a wide variety of wavelengths from the electromagnetic spectrum. Examples include, but are not limited to, in order of decreasing energy, vacuum ultraviolet (VUV) light, ultraviolet (UV) light, visible light, or infrared (IR) light. As those skilled in the art will readily recognize, the light energy may be chosen to facilitate the desired reaction on a substrate. The light energy that is chosen can, for example, depend on the energy needed to dissociate an adsorbed precursor layer. The activating light source may, for example, include a laser light source or a lamp light source capable of providing discrete light wavelengths or broadband light. Suitable light intensity levels that enable formation of films by ALD at improved deposition rates and with reduced impurities can be determined by direct experimentation and/or design of experiments (DOE).

In the example of a TaCN film, a Ta organic film precursor may contain a “Ta—N—C” structural unit, such as tertiary amyl imido-tris-dimethylamido tantalum (Ta(NC(CH₃)₂C₂H₅)(N(CH₃)₂)₃, hereinafter referred to as TAIMATA®. In another example, the Ta organic film precursor may include (pentakis(diethylamido) tantalum (Ta[N(C₂H₅)₂]₅, PDEAT), pentakis(ethylmethylamido) tantalum (Ta[N(C₂H₅CH₃)]₅, PEMAT), pentakis(mehylamido) tantalum (Ta[N(CH₃)₂]₅, PDMAT), (t-butylimino tris(diethylamino) tantalum (Ta(NC(CH₃)₃(N(C₂H₅)₂)₃, TBTDET), Ta(NC₂H₅)(N(C₂H₅)₂)₃, Ta(NC(CH₃)₃(N(CH₃)₂)₃, or tert-butyl-tris-ethylmethylamido tantalum Ta(NC(CH₃)₃)((NC₂H₅(CH₃)₃(₃), TBTEMAT).

In the example of a TaC film, a Ta organic film precursor may contain a “TC” structural unit, such as Ta(h⁵-C₅H₅)₂H₃, Ta(CH₂)(CH₃)(h⁵-C₅H₅)₂, Ta(h³-C₃H₅) (h⁵-C₅H₅)₂, Ta(CH₃)₃(h⁵-C₅H₅)₂, Ta(CH₃)₄(h⁵-C₅(CH₃)₅), or Ta(h⁵-C₅(CH₃)₅)₂H₃.

The wafer transfer station 32 is provided with a transfer volume 64 formed by a raised portion of the upper wall of the chamber 38. A lift mechanism 70 below the index plate 40 at the transfer station 32 raises lift pins 72 through holes in the one of the wafer holders 41-45 that is at the transfer station, as illustrated in FIG. 1A, to lift the wafer 25 that is at the transfer station 32 into the transfer volume 64. The lift mechanism 70 can, alternatively, raise an actuator (not shown) to engage lift pin sets that are provided in each of the wafer holders 41-45 (not shown).

The showerheads 60 at the precursor deposition stations 33 and 35 have an aperture plate 66 on the downwardly facing end thereof having an array of holes or precursor discharge orifices 67 therein, as shown in FIG. 4. Each of the holes 67 is provided with a MEMS (Micro Electrical Mechanical System) based constrictor, valve or baffle elements 80, mounted at the plate 67, to turn the flow on or off, or to adjust the flow rate through the holes 67. For turning the flow on and off, the element 80 can be a sliding shower plate orifice cover 81, as illustrated in FIG. 4A, which simply slides between open and closed positions to open or close the hole 67. Typically, each of the elements is actuated simultaneously. For controlling the precursor gas flow through the holes 67 at different flow rates, a rotating multiple-aperture orifice cover 82 can be used for each of the elements 80, as illustrated in FIG. 4B. The rotating element 82 can have a series of holes that vary in size from smallest 83, to intermediate sizes 84 and 85 and to largest 86, which is the size of the hole 67.

In the operation of the illustrated embodiment of the module 30, a wafer 25 is loaded onto a wafer holder at the transfer station 32, then the plate 40 is indexed, in this case 72 degrees, to move the first loaded wafer to precursor deposition station 33, where coating is deposited onto that wafer while another wafer is loaded onto the next wafer holder at the transfer station 32. Then the plate is indexed again, moving the coated wafer from deposition station 33 to activation station 34 and a wafer from transfer station 32 to deposition station 33. The steps continue until all holders on the plate 40 are loaded, then continues further to rotate the loaded wafers repeatedly around the stations until enough deposition and activation cycles have taken place to deposit completed films on the wafers. In the last rotation of the plate 40, completed wafers are removed from each of the holders as they pass through the transfer station 32.

Although only certain exemplary embodiments of this invention have been described in detail above, those skilled in the art will readily appreciate that many modifications arc possible in the exemplary embodiments without materially departing from the novel teachings and advantages of this invention. Accordingly, all such modifications are intended to be included within the scope of this invention.

What is claimed is:

1. An ALD processing module comprising:
a chamber;
a wafer carrier rotatably mounted within the chamber and having a plurality of wafer holders thereon;
a series of process stations in the chamber, including at least precursor deposition station at which precursor is deposited on the wafer and at least one light activation at which deposited precursor on the wafer is activated by exposure to light;
the carrier being configured such that a wafer on one of the holders is positioned in a precursor deposition station while another of the wafers on another holder is positioned in a light activation station;
a controller;
the carrier being operable in response to signals from the controller to move wafers on the respective holders successively through a plurality of cycles that include positioning the wafer to receive precursor deposition at a precursor deposition station, then receiving exposure to light to activate deposited precursor at a light activation station.

2. The ALD processing module of claim 1 further comprising:
means within the chamber for isolating the light activation chambers from the precursor deposition stations to separate a precursor gas environment at deposition stations from a carrier gas environment at activation stations.

3. The ALD processing module of claim 1 further comprising:
a transfer station in the chamber.

4. The ALD processing module of claim 1 wherein:
the carrier has a number of wafer holders thereon corresponding to the number of stations in the chamber.

5. A method of applying an ALD film to a substrates comprising:
rotating a plurality of substrates on a carrier a plurality of times through a circular array of stations that include a plurality of precursor deposition stations and art equal plurality of light activation stations arranged with one activation station following each deposition station; and
simultaneously depositing precursor on a wafer at each of a plurality of deposition stations while activating precursor on a wafer at each of the plurality of activation stations.
